(19) United States
(12) Patent Application Publication
(10) Pub. No.: US 2026/0026139 A1
(43) Pub. Date: Jan. 22, 2026

(54) LIGHT-EMITTING DIODE STRUCTURE AND MANUFACTURING METHOD THEREOF

(71) Applicant: GUANGZHOU LUXVISIONS INNOVATION TECHNOLOGY LIMITED, Guangzhou City (CN)

(72) Inventors: Yi-Chih Lai, Guangzhou City (CN); Wei-Han Wu, Guangzhou City (CN)

(73) Assignee: GUANGZHOU LUXVISIONS INNOVATION TECHNOLOGY LIMITED, Guangzhou City (CN)

(21) Appl. No.: 19/096,766

(22) Filed: Apr. 1, 2025

Related U.S. Application Data
(60) Provisional application No. 63/672,220, filed on Jul. 16, 2024.

(30) Foreign Application Priority Data
Sep. 24, 2024 (CN) 202411335104.8

(51) Int. Cl. H10H 20/84; H10H 20/01; H10H 20/851; H10H 20/856

(52) U.S. Cl. CPC H10H 20/84; H10H 20/021; H10H 20/034; H10H 20/0361; H10H 20/0363; H10H 20/8512; H10H 20/8515; H10H 20/856

(57) ABSTRACT

A light-emitting diode structure and a manufacturing method thereof are provided. The light-emitting diode structure includes a substrate, a light-emitting diode chip, a wavelength conversion layer, and a short-pass filter coating. The light-emitting diode chip is disposed on the substrate in a flip-chip manner and is used to emit a first light beam. The wavelength conversion layer is disposed on the light-emitting diode chip and is used to convert a part of the first light beam into a second light beam. A wavelength of the first light beam is less than a wavelength of the second light beam. The short-pass filter coating is disposed between the wavelength conversion layer and the light-emitting diode chip, allowing the first light beam to pass through and reflecting the second light beam.

### CROSS-REFERENCE TO RELATED APPLICATION

This application claims the priority benefit of U.S. provisional application Ser. No. 63/672,220, filed on Jul. 16, 2024 and China application serial no. 202411335104.8, filed on Sep. 24, 2024. The entirety of each of the above-mentioned patent applications is hereby incorporated by reference herein and made a part of this specification.

### BACKGROUND

### Technical Field

The disclosure relates to a light-emitting structure, and in particular to a light-emitting diode structure and a manufacturing method thereof.

### Description of Related Art

Existing white light-emitting diodes are formed by covering a blue light-emitting diode chip with yellow phosphor. When the blue light emitted by the blue light-emitting diode chip irradiates the yellow phosphor, a portion of the blue light excites the yellow phosphor and generates yellow light. In other words, the yellow phosphor converts a portion of the blue light into yellow light. The remaining portion of the blue light, which is not converted into yellow light by the yellow phosphor, mixes with the yellow light to form white light.

However, when the blue light excites the yellow phosphor and generates yellow light, although a portion of the yellow light is transmitted in a direction away from the blue light-emitting diode chip to form effective light, another portion of the yellow light is transmitted toward the blue light-emitting diode chip, causing partial light intensity loss.

Additionally, the yellow phosphor is mixed into encapsulation adhesive and covered on the blue light-emitting diode chip. Due to the difference in refractive index between the blue light-emitting diode chip and the encapsulation adhesive, Fresnel loss occurs when the blue light is transmitted to the interface between the blue light-emitting diode chip and the encapsulation adhesive. As a result, the blue light is reflected into the interior of the blue light-emitting diode chip at the interface, causing light intensity loss.

### SUMMARY

The disclosure relates to a light-emitting diode structure that effectively reduces light intensity loss and improves light efficiency.

The disclosure also relates to a manufacturing method of a light-emitting diode structure that enables the fabrication of a light-emitting diode structure with high light efficiency.

An embodiment of the disclosure provides a light-emitting diode structure, including a substrate, a light-emitting diode chip, a wavelength conversion layer, and a short-pass filter coating. The light-emitting diode chip is disposed on the substrate in a flip-chip manner and is used to emit a first light beam. The wavelength conversion layer is disposed on the light-emitting diode chip and is used to convert a part of the first light beam into a second light beam. A wavelength of the first light beam is less than a wavelength of the second light beam. The short-pass filter coating is disposed between the wavelength conversion layer and the light-emitting diode chip, allowing the first light beam to pass through and reflecting the second light beam.

An embodiment of the disclosure provides a manufacturing method of a light-emitting diode structure. The manufacturing method includes the following steps. A plurality of light-emitting diode chips are provided. Each of the plurality of light-emitting diode chips has an electrode, and a short-pass filter coating is disposed on a side of the each of the plurality of light-emitting diode chips facing away from the electrode. The plurality of light-emitting diode chips are disposed on a first temporary substrate, with the electrode facing the first temporary substrate. The plurality of light-emitting diode chips are covered with a wavelength conversion layer. The wavelength conversion layer is cut. The plurality of light-emitting diode chips are separated from the first temporary substrate, and the each of the plurality of light-emitting diode chips is bonded, along with the short-pass filter coating and the cut wavelength conversion layer, to a substrate.

An embodiment of the disclosure provides a manufacturing method of a light-emitting diode structure. The manufacturing method includes the following steps. A plurality of light-emitting diode chips are provided. Each of the plurality of light-emitting diode chips has an electrode, and a short-pass filter coating is disposed on a side of the each of the plurality of light-emitting diode chips facing away from the electrode. The plurality of light-emitting diode chips are disposed on a substrate, with the electrode facing the substrate. The plurality of light-emitting diode chips are covered with a wavelength conversion layer. The wavelength conversion layer is cut. The substrate is cut to form a plurality of separated light-emitting diode structures.

In the light-emitting diode structure and the manufacturing method in the embodiments of the disclosure, the short-pass filter coating allows the first light beam emitted from the light-emitting diode chip to pass through and reflects the second light beam from the wavelength conversion layer. As a result, loss of the second light beam transmitted into the light-emitting diode chip is effectively reduced, thereby improving the light efficiency of the light-emitting diode structure.

### BRIEF DESCRIPTION OF THE DRAWINGS

FIG. 1 is a cross-sectional schematic diagram of a light-emitting diode structure according to an embodiment of the disclosure.

FIGS. 2A and 2B are spectral diagrams of two embodiments of the first light beam and the second light beam in FIG. 1.

FIG. 3 illustrates a detailed structure of the light-emitting diode chip and the short-pass filter coating in FIG. 1.

FIG. 4 illustrates a detailed film layer of the short-pass filter coating in FIG. 1.

FIG. 5 is a transmittance spectrum diagram of the short-pass filter coating in FIG. 1 under multiple different incident angles.

FIG. 6 is a light intensity percentage distribution diagram of the light-emitting diode structure in FIG. 1 and a light-emitting diode structure without the short-pass filter coating at various emission angles.

FIG. 7 is a cross-sectional schematic diagram of a light-emitting diode structure according to another embodiment of the disclosure.

FIG. 8 is a cross-sectional schematic diagram of a light-emitting diode structure according to yet another embodiment of the disclosure.

FIG. 9A is a cross-sectional schematic diagram of a light-emitting diode structure according to still another embodiment of the disclosure.

FIG. 9B is a cross-sectional schematic diagram of a light-emitting diode structure according to another embodiment of the disclosure.

FIG. 10A is a cross-sectional schematic diagram of a light-emitting diode structure according to yet another embodiment of the disclosure.

FIG. 10B illustrates a detailed structure of the light-emitting diode chip and the short-

pass filter coating in FIG. 10A.

FIGS. 11A to 11I are cross-sectional schematic diagrams illustrating the process flow of a manufacturing method of a light-emitting diode structure according to an embodiment of the disclosure.

FIGS. 12A to 12F are cross-sectional schematic diagrams illustrating the process flow of a manufacturing method of a light-emitting diode structure according to another embodiment of the disclosure.

FIGS. 13A and 13B are cross-sectional schematic diagrams illustrating part of the process flow of a manufacturing method of a light-emitting diode structure according to yet another embodiment of the disclosure.

FIG. 14 is a cross-sectional schematic diagram illustrating one step in the manufacturing method of a light-emitting diode structure according to another embodiment of the disclosure.

FIGS. 15A to 15D are cross-sectional schematic diagrams illustrating the process flow of a manufacturing method of a light-emitting diode structure according to another embodiment of the disclosure.

FIGS. 16A and 16B are cross-sectional schematic diagrams illustrating part of the process flow of a manufacturing method of a light-emitting diode structure according to another embodiment of the disclosure.

FIGS. 17A to 17C are cross-sectional schematic diagrams illustrating part of the process flow of a manufacturing method of a light-emitting diode structure according to another embodiment of the disclosure.

FIGS. 18A to 18D are cross-sectional schematic diagrams illustrating the process flow of a manufacturing method of a light-emitting diode structure according to another embodiment of the disclosure.

FIGS. 19A to 19C are cross-sectional schematic diagrams illustrating the process flow of a manufacturing method of a light-emitting diode structure according to another embodiment of the disclosure.

### DESCRIPTION OF THE EMBODIMENTS

The exemplary embodiments of the disclosure will now be described in detail with reference to the accompanying drawings. Wherever possible, the same reference numerals are used in the drawings and descriptions to represent the same or similar parts.

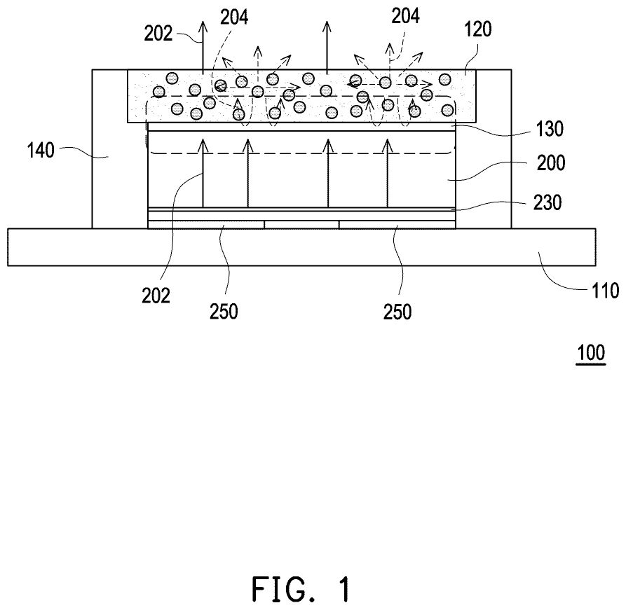

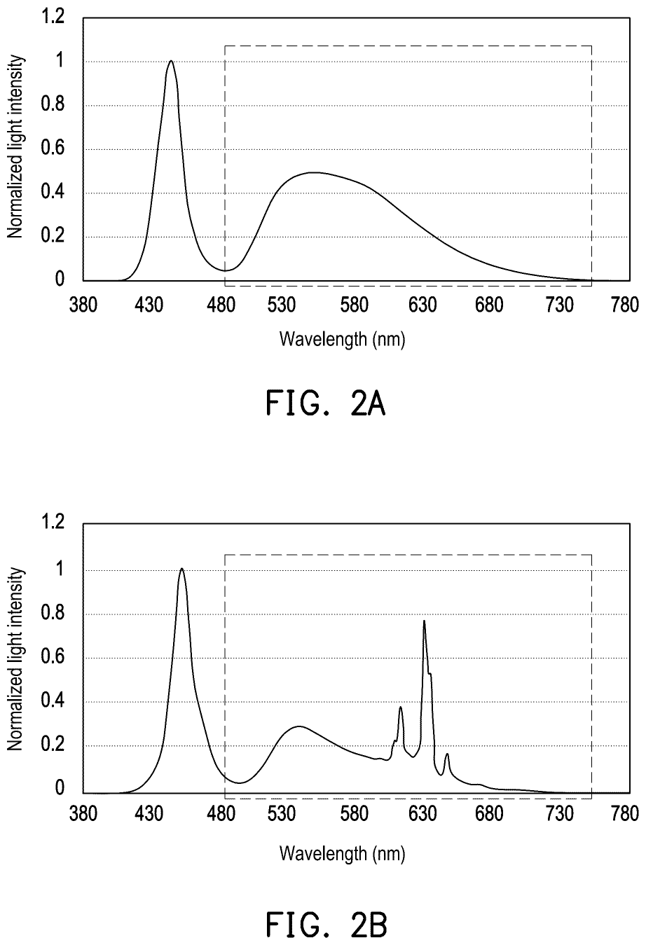

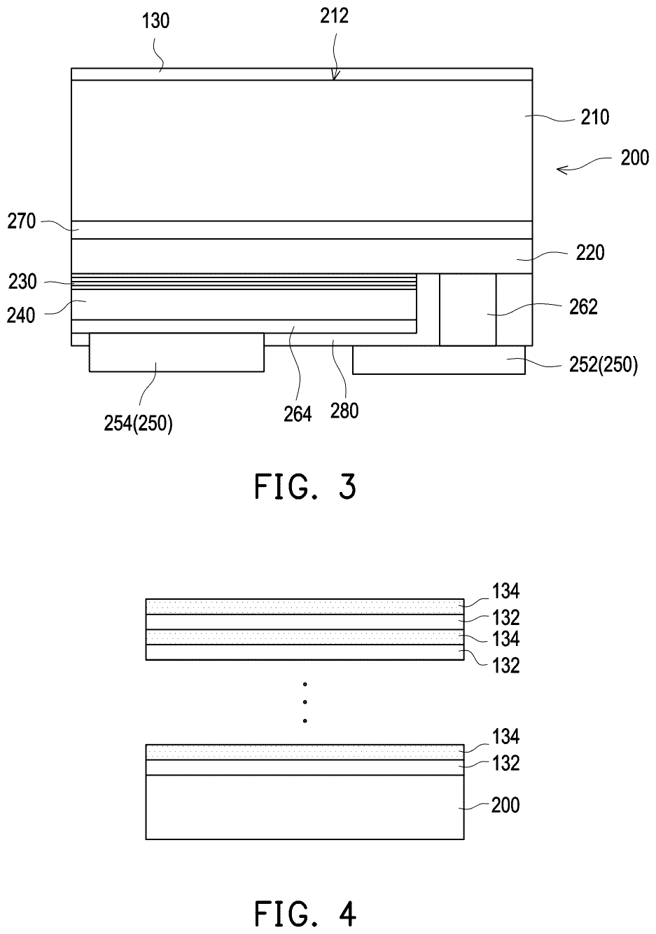

FIG. 1 is a cross-sectional schematic diagram of a light-emitting diode structure according to an embodiment of the disclosure. FIGS. 2A and 2B are spectral diagrams of two embodiments of the first light beam and the second light beam in FIG. 1. FIG. 3 illustrates a detailed structure of the light-emitting diode chip and the short-pass filter coating in FIG. 1. Referring to FIGS. 1, 2A, 2B, and 3, a light-emitting diode structure 100 in this embodiment includes a substrate 110, a light-emitting diode chip 200, a wavelength conversion layer 120, and a short-pass filter coating 130. The light-emitting diode chip 200 is disposed on the substrate 110 in a flip-chip manner and is used to emit a first light beam 202. The wavelength conversion layer 120 is disposed on the light-emitting diode chip 200 and is used to convert a part of the first light beam 202 into a second light beam 204, wherein a wavelength of the first light beam 202 is less than a wavelength of the second light beam 204. The wavelength conversion layer 120 is, for example, a phosphor layer or a quantum dot layer. In this embodiment, the first light beam 202 is, for example, blue light, and the second light beam 204 is, for example, yellow light, red light, or a combination thereof. As shown in FIGS. 2A and 2B, the left side outside the dashed box represents the spectrum of the first light beam 202, while the spectrum inside the dashed box represents the spectrum of the second light beam 204. In FIG. 2A, the spectrum inside the dashed box represents the spectrum of the second light beam 204 as yellow light. In this case, the wavelength conversion layer 120 contains yellow phosphor or yellow quantum dots. In FIG. 2B, the spectrum inside the dashed box represents the spectrum of the second light beam 204 as a combination of yellow light and red light. In this case, the wavelength conversion layer 120 contains both yellow phosphor and red phosphor or contains both yellow quantum dots and red quantum dots.

The short-pass filter coating 130 is disposed between the wavelength conversion layer 120 and the light-emitting diode chip 200, allowing the first light beam 202 to pass through and reflecting the second light beam 204. In this embodiment, the short-pass filter coating 130 is disposed on a side of the light-emitting diode chip 200 away from the substrate 110. Additionally, in this embodiment, the wavelength conversion layer 120 is disposed on a side of the short-pass filter coating 130 away from the substrate 110, and the light-emitting diode structure 100 further includes a reflective layer 140 disposed on a side surface of the light-emitting diode chip 200. In this embodiment, the reflective layer 140 covers a side surface of the wavelength conversion layer 120, as shown in FIG. 1.

In this embodiment, the light-emitting diode chip 200 includes a growth substrate 210, a first type semiconductor layer 220, a light-emitting layer 230, a second type semiconductor layer 240, and an electrode 250. The short-pass filter coating 130 is disposed on a surface 212 of the growth substrate 210 facing away from the substrate 110 (as shown in FIG. 1, located below the light-emitting diode chip 200 in FIG. 3). The first type semiconductor layer 220 is disposed between the growth substrate 210 and the substrate 110. The light-emitting layer 230 is disposed between the first type semiconductor layer 220 and the substrate 110. The second type semiconductor layer 240 is disposed between the light-emitting layer 230 and the substrate 110. The electrode 250 (as shown in FIGS. 1 and 3) is disposed between the second type semiconductor layer 240 and the substrate 110 and is electrically connected to the substrate 110.

In this embodiment, the electrode 250 may be divided into a first electrode 252 and a second electrode 254. The first electrode 252 may be electrically connected to the first type semiconductor layer 220 via a conductive through via 262, while the second electrode 254 may be electrically connected to the second type semiconductor layer 240 via a conductive layer 264. Additionally, a buffer layer 270 may be disposed between the growth substrate 210 and the first type semiconductor layer 220. In this embodiment, the first type and the second type are respectively N-type and P-type. However, in other embodiments, the first type and the second type may be P-type and N-type. Additionally, the light-emitting diode chip 200 may include an insulating layer 280, which covers the second type semiconductor layer 240 and the light-emitting layer 230 but exposes the second electrode 254 and isolates the light-emitting layer 230 from the conductive through via 262 and the second type semiconductor layer 240 from the conductive through via 262.

In the light-emitting diode structure 100 in this embodiment, the short-pass filter coating 130 allows the first light beam 202 emitted by the light-emitting diode chip 200 to pass through and reflects the second light beam 204 from the wavelength conversion layer 120. As a result, loss of the second light beam 204 transmitted into the interior of the light-emitting diode chip 200 is effectively reduced, thereby improving the light efficiency of the light-emitting diode structure 100. Specifically, after passing through the short-pass filter coating 130, the first light beam 202 emitted by the light-emitting diode chip 200 is transmitted to the wavelength conversion layer 120. The wavelength conversion layer 120 converts a portion of the first light beam 202 into the second light beam 204. At this time, the second light beam 204 propagates in multiple directions. The short-pass filter coating 130 reflects the second light beam 204 traveling in the direction of the substrate 110 to prevent the second light beam 204 from entering the interior of the light-emitting diode chip 200 and causing light intensity loss. Additionally, the short-pass filter coating 130 directs the second light beam 204 in a direction away from the substrate 110 to form effective light. In this way, the light efficiency of the light-emitting diode structure 100 may be effectively improved. On the other hand, the short-pass filter coating 130 has an anti-reflection effect on the first light beam 202, allowing a higher proportion of the first light beam 202 to pass through the short-pass filter coating 130 and reach the wavelength conversion layer 120. This effectively reduces interface reflection and thereby enhances light efficiency.

In an embodiment, the material of the reflective layer 140 may include resin and scattering particles dispersed in the resin. The resin may be, for example, epoxy resin, silicone resin, polymethyl methacrylate, ultraviolet glue (UV glue), or photoresist. The scattering particles may be, for example, titanium dioxide, silicon dioxide, or boron nitride. The material of the wavelength conversion layer 120 may include resin or glass and phosphor dispersed in the resin or glass. The resin may be, for example, epoxy resin, silicone resin, polymethyl methacrylate, ultraviolet glue, or photoresist. The glass may be, for example, silicate glass, soda-lime glass, borosilicate glass, or lead glass. The phosphor may be, for example, silicate phosphor, nitride phosphor, nitride yttrium aluminum garnet phosphor, yttrium aluminum garnet phosphor, potassium fluorosilicate phosphor, aluminate phosphor, α-silicon aluminum oxynitride (alpha-SiAlON) phosphor, or β-silicon aluminum oxynitride (beta-SiAlON) phosphor. The substrate 110 may be, for example, a printed circuit board, a metal core printed circuit board, a ceramic substrate, a plastic leaded chip carrier (PLCC), or a glass substrate. The material of the electrode 250 may be metal or alloy. The metal may be, for example, gold, tin, silver, copper, or a combination thereof. The alloy may be, for example, a gold-tin alloy or another alloy.

In an embodiment, the material of the growth substrate 210 includes silicon (Si), silicon carbide (SiC), gallium nitride (GaN), sapphire, zinc oxide (ZnO), gallium arsenide (GaAs), or gallium phosphide (GaP). The material of the buffer layer 270 may be, for example, gallium nitride, aluminum nitride (AlN), or gallium arsenide. The first type semiconductor layer 220 may be, for example, N-type GaN, AlN, GaAs, or GaP. The second type semiconductor layer 240 may be, for example, P-type GaN, AlN, GaAs, or GaP. The material of the light-emitting layer 230 may be, for example, GaN and AlGaN alternately stacked, GaN and InGaN alternately stacked, GaP and AlGaInP alternately stacked, GaP and GaAs alternately stacked, GaAs and AlGaAs alternately stacked, or GaAs and GaAsP alternately stacked. The material of the conductive layer 264 may be, for example, gallium phosphide, indium tin oxide, or nickel. The material of the insulating layer 280 may be, for example, silicon dioxide, silicon nitride, aluminum oxide, titanium dioxide, zinc oxide, or chromium oxide.

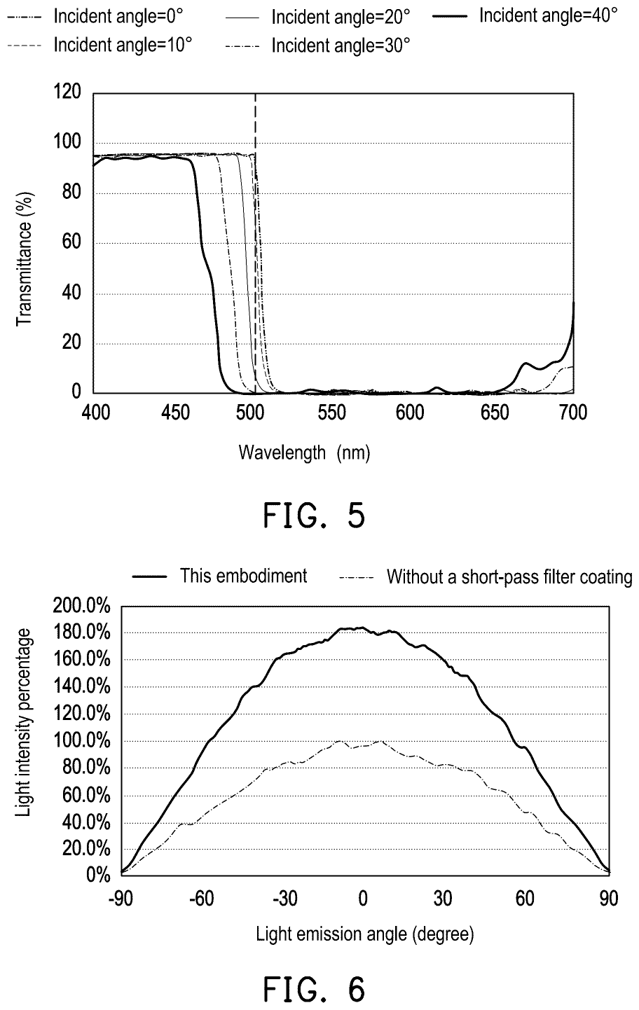

FIG. 4 illustrates a detailed film layer of the short-pass filter coating in FIG. 1, and FIG. 5 is a transmittance spectrum diagram of the short-pass filter coating in FIG. 1 under multiple different incident angles. Referring to FIGS. 1, 3, and 4, in this embodiment, the short-pass filter coating 130 includes multiple low refractive index layers 132 and multiple high refractive index layers 134. The low refractive index layers 132 and the high refractive index layers 134 are alternately stacked on the light-emitting diode chip 200. The refractive index of the high refractive index layers 134 is greater than the refractive index of the low refractive index layers 132. In this embodiment, the difference between the refractive index of the high refractive index layers 134 and the refractive index of the low refractive index layers 132 is greater than 0.5. In an embodiment, the material of the low refractive index layers 132 is tantalum pentoxide, and the material of the high refractive index layers 134 is silicon dioxide. However, the disclosure is not limited thereto. The material of the short-pass filter coating 130 may be metal or dielectric material. The metal may be any combination of gold, tin, silver, and aluminum. The dielectric material may be any combination of silicon dioxide, tantalum pentoxide, and silicon. In this embodiment, referring to FIG. 5, in terms of the transmittance spectrum for an incident angle of 0 degrees (i.e., the optical axis direction of the light-emitting diode structure 100), the transmittance of the short-pass filter coating 130 for light with a wavelength less than 500 nanometers (nm) is greater than 90%, while the transmittance of the short-pass filter coating 130 for light with a wavelength greater than 500 nanometers is less than 5%. In an embodiment, the total number of the low refractive index layers 132 and the high refractive index layers 134 is less than 500 layers, and the thickness of a single layer of the low refractive index layers 132 and the high refractive index layers 134 is about 0.1 nanometers to 100 nanometers.

FIG. 6 is a light intensity percentage distribution diagram of the light-emitting diode structure in FIG. 1 and a light-emitting diode structure without the short-pass filter coating at various emission angles. Referring to FIGS. 1 and 6, the curve labeled “this embodiment” represents the curve of the light-emitting diode structure 100 in FIG. 1. The curve labeled “without a short-pass filter coating” represents the curve of the light-emitting diode structure 100 in FIG. 1 after removing the short-pass filter coating 130, with the wavelength conversion layer 120 directly formed on the light-emitting diode chip 200. This structure is hereinafter referred to as “the light-emitting diode structure without the short-pass filter coating.” In FIG. 6, the direction of an emission angle of 0 degrees refers to the optical axis direction of the light-emitting diode structure. The maximum light intensity among various emission angles of the light-emitting diode structure without the short-pass filter coating is defined as 100% light intensity percentage. As shown in FIG. 6, the light-emitting diode structure 100 in this embodiment in FIG. 1 may enhance the light intensity by 80%. This confirms that the light-emitting diode structure 100 in this embodiment may effectively improve light efficiency.

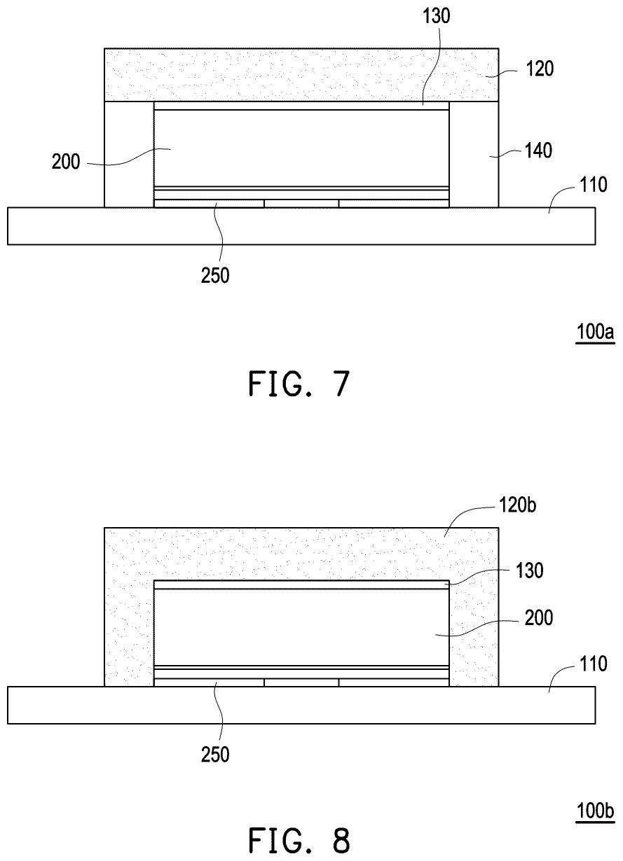

FIG. 7 is a cross-sectional schematic diagram of a light-emitting diode structure according to another embodiment of the disclosure. Referring to FIG. 7, a light-emitting diode structure 100a in this embodiment is similar to the light-emitting diode structure 100 in FIG. 1. The main difference between them is that, in the light-emitting diode structure 100a in this embodiment, the wavelength conversion layer 120 covers the top surface of the reflective layer 140.

FIG. 8 is a cross-sectional schematic diagram of a light-emitting diode structure according to yet another embodiment of the disclosure. Referring to FIG. 8, a light-emitting diode structure 100b in this embodiment is similar to the light-emitting diode structure 100 in FIG. 1. The main difference between them is that, in the light-emitting diode structure 100b in this embodiment, a wavelength conversion layer 120b covers a side of the short-pass filter coating 130 away from the substrate 110 and a side surface of the light-emitting diode chip 200.

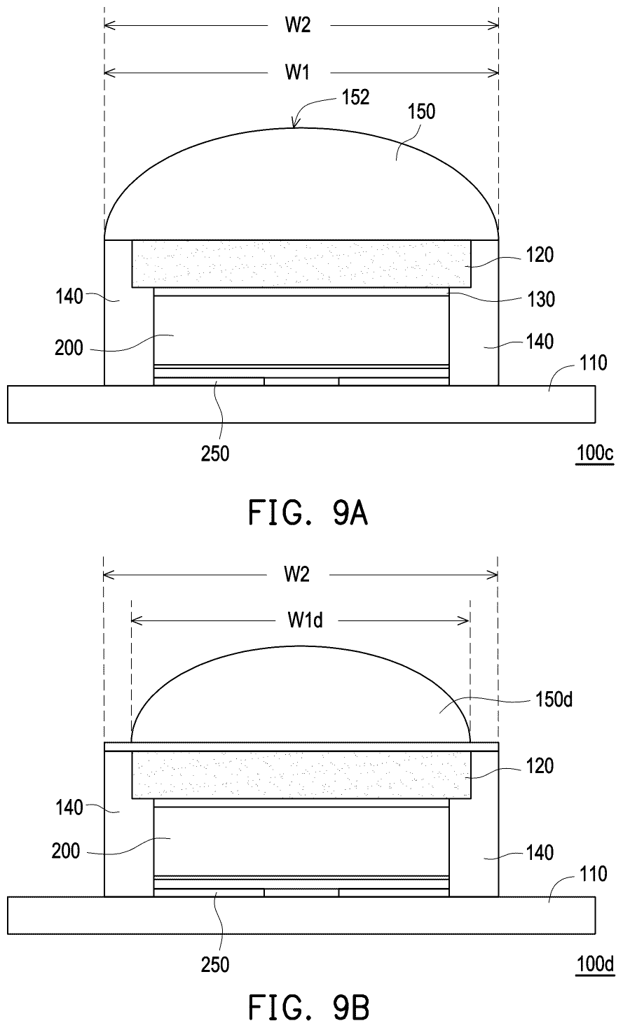

FIG. 9A is a cross-sectional schematic diagram of a light-emitting diode structure according to still another embodiment of the disclosure. Referring to FIG. 9A, a light-emitting diode structure 100c in this embodiment is similar to the light-emitting diode structure 100 in FIG. 1. The main difference between them is that the light-emitting diode structure 100c in this embodiment further includes a lens 150 disposed on the wavelength conversion layer 120.

FIG. 9B is a cross-sectional schematic diagram of a light-emitting diode structure according to another embodiment of the disclosure. Referring to FIG. 9B, a light-emitting diode structure 100d in this embodiment is similar to the light-emitting diode structure 100c in FIG. 9A. The main difference between them is that, in FIG. 9A, a width W1 of a refractive surface 152 of the lens 150 is equal to a width W2 of the reflective layer 140, while in FIG. 9B, a width W1d of the refractive surface 152d of the lens 150d is smaller than the width W2 of the reflective layer 140.

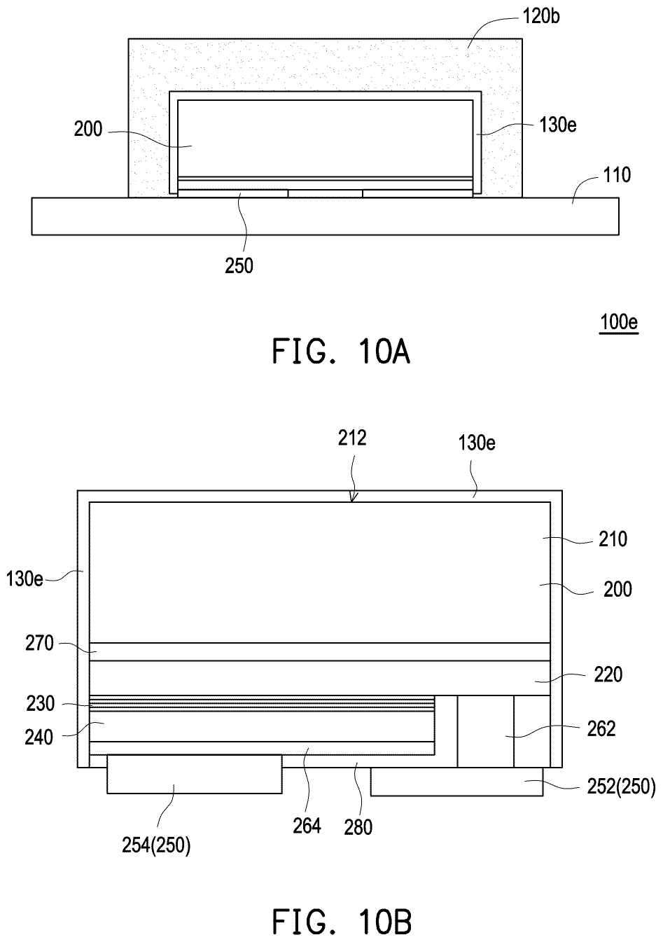

FIG. 10A is a cross-sectional schematic diagram of a light-emitting diode structure according to yet another embodiment of the disclosure. FIG. 10B illustrates a detailed structure of the light-emitting diode chip and the short-pass filter coating in FIG. 10A. Referring to FIGS. 10A and 10B, a light-emitting diode structure 100e in this embodiment is similar to the light-emitting diode structure 100b in FIG. 8. The main differences between them are as follows. In the light-emitting diode structure 100e in this embodiment, a short-pass filter coating 130e covers a side of the light-emitting diode chip 200 away from the substrate 110 and a side surface of the light-emitting diode chip 200. Additionally, the wavelength conversion layer 120b covers a side of the short-pass filter coating 130e away from the substrate 110 and a side of the short-pass filter coating 130e away from the side surface of the light-emitting diode chip 200.

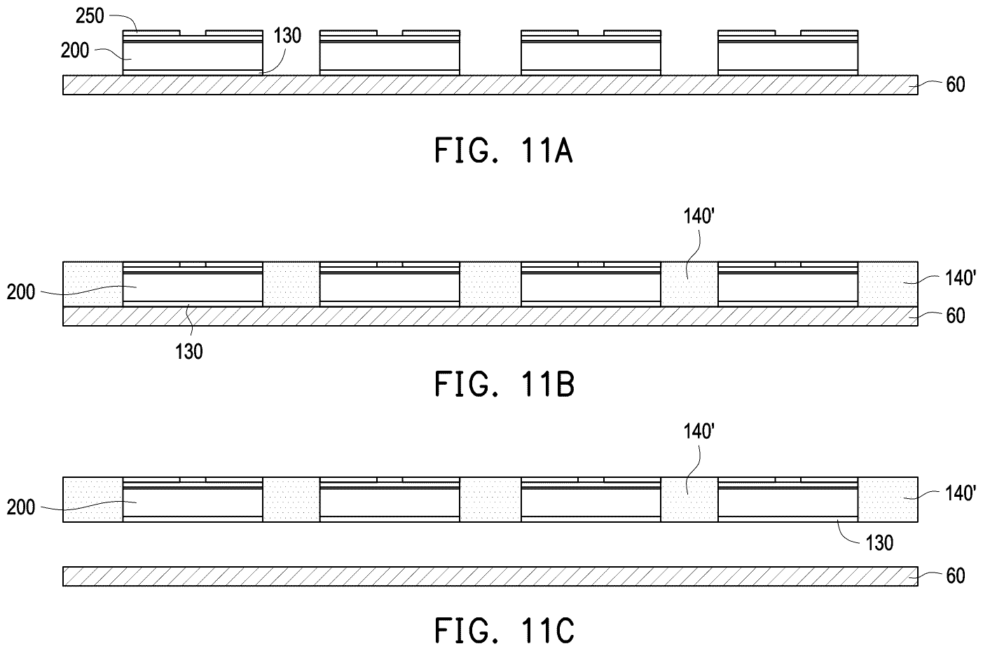

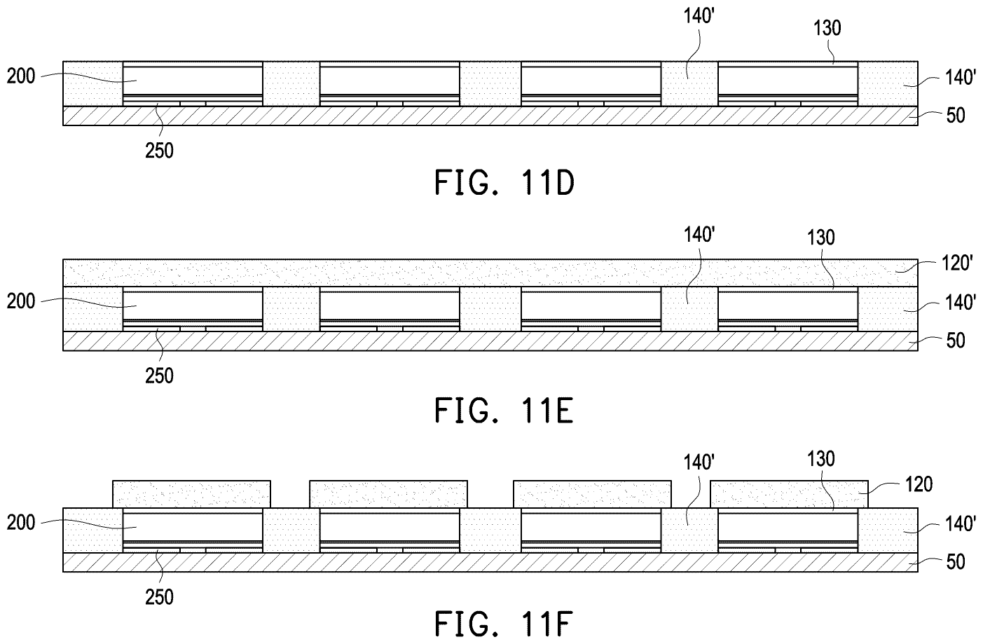

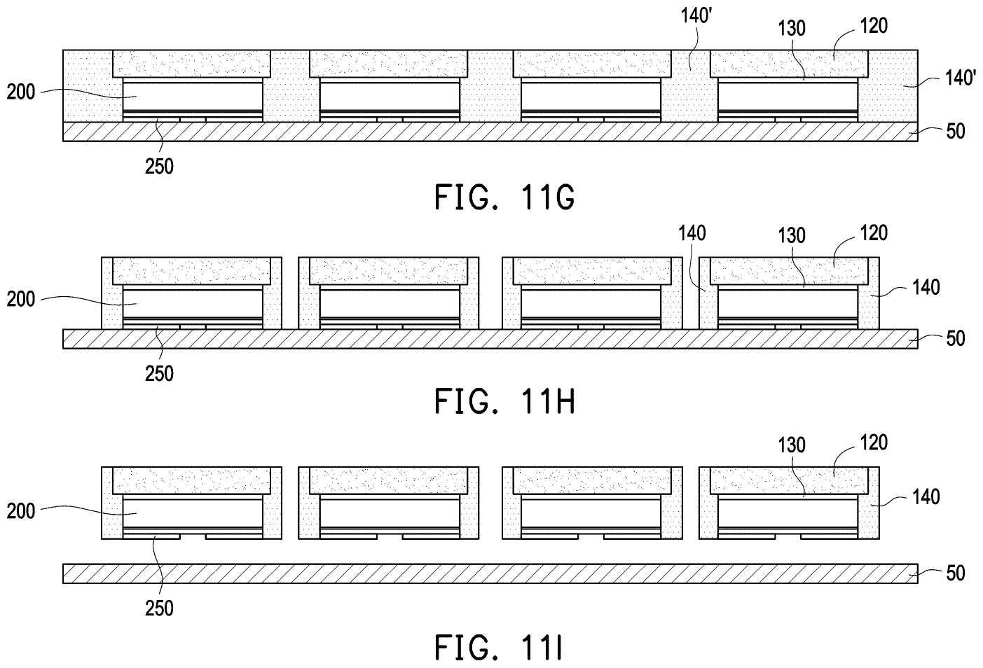

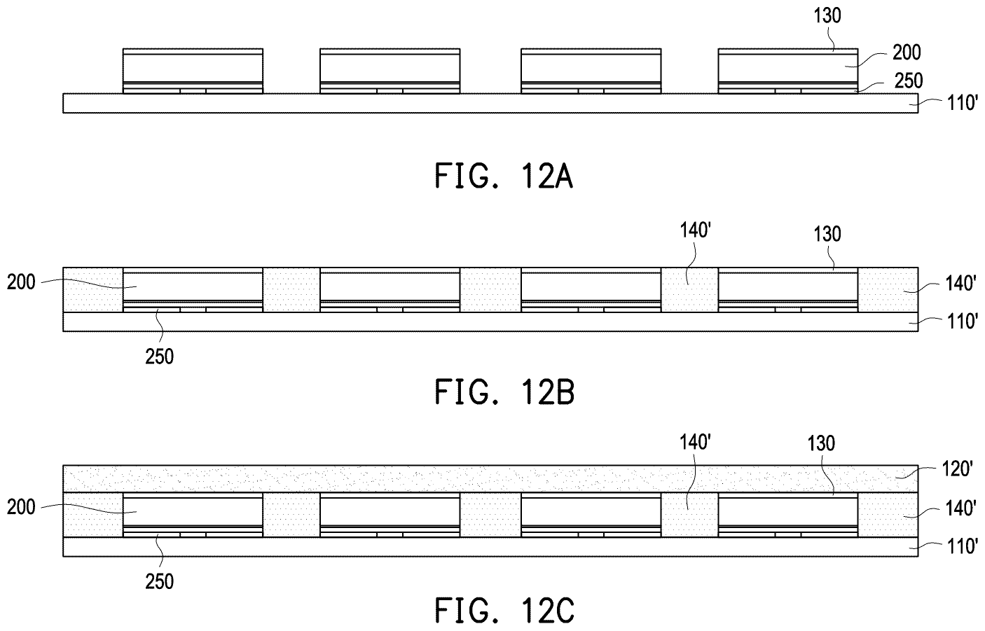

FIGS. 11A to 11I are cross-sectional schematic diagrams illustrating the process flow of a manufacturing method of a light-emitting diode structure according to an embodiment of the disclosure. Referring to FIGS. 11A to 11I, the manufacturing method of the light-emitting diode structure in this embodiment may be used to manufacture the light-emitting diode structures in the above embodiments. The following description takes the manufacturing of the light-emitting diode structure 100 in FIG. 1 as an example. The manufacturing method of the light-emitting diode structure in this embodiment includes the following steps. First, referring to FIG. 11A, a plurality of light-emitting diode chips 200 are provided, wherein each of the light-emitting diode chips 200 has an electrode 250, and a short-pass filter coating 130 is disposed on a side of each light-emitting diode chip 200 facing away from the electrode 250. The details of the light-emitting diode chip 200 and the short-pass filter coating 130 have been described in the above embodiments and will not be repeated here. In a subsequent step, referring to FIG. 11D, the light-emitting diode chips 200 are disposed on a first temporary substrate 50, with the electrode 250 facing the first temporary substrate 50.

In this embodiment, before disposing the light-emitting diode chips 200 on the first temporary substrate 50, that is, before the step in FIG. 11D, referring to FIG. 11A, the light-emitting diode chips 200 are first disposed on a second temporary substrate 60, with the electrode 250 facing away from the second temporary substrate 60. Then, referring to FIG. 11B, a reflective layer 140′ is filled into the gaps between adjacent light-emitting diode chips 200 on the second temporary substrate 60. Next, referring to FIG. 11C, the light-emitting diode chips 200, along with the reflective layer 140′ and the short-pass filter coating 130, are separated from the second temporary substrate 60. Afterward, as shown in FIG. 11D, the light-emitting diode chips 200, along with the reflective layer 140′ and the short-pass filter coating 130, are disposed on the first temporary substrate 50, with the electrode 250 facing the first temporary substrate 50.

Next, as shown in FIG. 11E, the light-emitting diode chips 200 are covered with a wavelength conversion layer 120′. In this embodiment, the wavelength conversion layer 120′ also covers the reflective layer 140 and the short-pass filter coating 130. Then, referring to FIG. 11F, the wavelength conversion layer 120′ is cut to form multiple separated wavelength conversion layers 120, wherein each of the wavelength conversion layers 120 is positioned on the short-pass filter coating 130. Next, as shown in FIG. 11G, in this embodiment, the gaps between the multiple cut wavelength conversion layers 120 may be filled with a reflective layer 140′. Then, referring to FIG. 11H, the reflective layer 140′ is cut to form multiple separated reflective layers 140, wherein each reflective layer 140 is positioned on a side surface of the light-emitting diode chip 200.

Then, referring to FIG. 11I, the light-emitting diode chips 200 are separated from the first temporary substrate 50. Next, referring to FIG. 1, each light-emitting diode chip 200, along with the short-pass filter coating 130 and the cut wavelength conversion layer 120, is bonded to a substrate 110. In this way, the fabrication of the light-emitting diode structure 100 is completed. The light-emitting diode structure manufactured by the manufacturing method in this embodiment (e.g., the light-emitting diode structure 100) may achieve the same effects as those described in the above embodiments for the light-emitting diode structure 100, and thus, these details will not be repeated here.

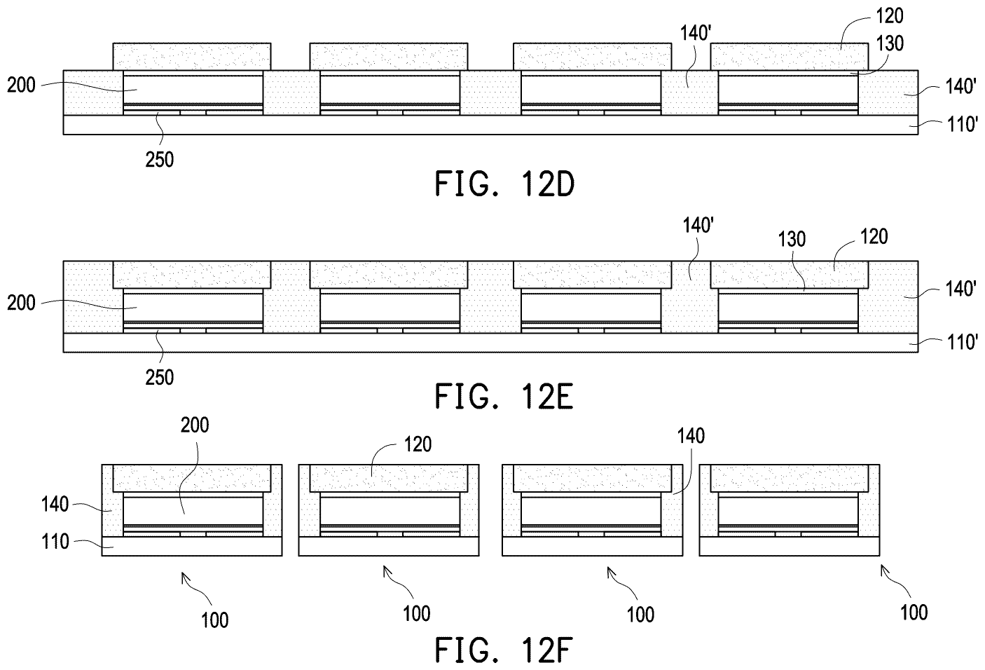

FIGS. 12A to 12F are cross-sectional schematic diagrams illustrating the process flow of a manufacturing method of a light-emitting diode structure according to another embodiment of the disclosure. Referring to FIGS. 12A to 12F, the manufacturing method of the light-emitting diode structure in this embodiment may be used to manufacture the light-emitting diode structures in the above embodiments. The following description takes the manufacturing of the light-emitting diode structure 100 in FIG. 1 as an example. The manufacturing method of the light-emitting diode structure in this embodiment includes the following steps. First, referring to FIG. 12A, a plurality of light-emitting diode chips 200 are provided, wherein each light-emitting diode chip 200 has an electrode 250, and a short-pass filter coating 130 is disposed on a side of each light-emitting diode chip 200 facing away from the electrode 250. The details of the light-emitting diode chip 200 and the short-pass filter coating 130 have been described in the above embodiments and will not be repeated here. Then, the light-emitting diode chips 200 are disposed on a substrate 110′, with the electrode 250 facing the substrate 110′. In this embodiment, as shown in FIG. 12B, a reflective layer 140′ is then filled into the gaps between the plurality of adjacent light-emitting diode chips 200 on the substrate 110′. Afterward, referring to FIG. 12C, the light-emitting diode chips 200 are covered with a wavelength conversion layer 120′. Next, referring to FIG. 12D, the wavelength conversion layer 120′ is cut to form multiple separated wavelength conversion layers 120, wherein each of the wavelength conversion layers 120 is positioned on the short-pass filter coating 130. In this embodiment, referring to FIG. 12E, the gaps between the multiple cut wavelength conversion layers 120 may then be filled with a reflective layer 140′. Next, referring to FIG. 12F, the substrate 110′ is cut to form multiple separated light-emitting diode structures 100. In this embodiment, when the substrate 110′ is cut, the reflective layer 140′ is also cut. After the substrate 110′ is cut, the substrate 110′ becomes multiple separated substrates 110, and after the reflective layer 140′ is cut, the reflective layer 140′ becomes multiple separated reflective layers 140.

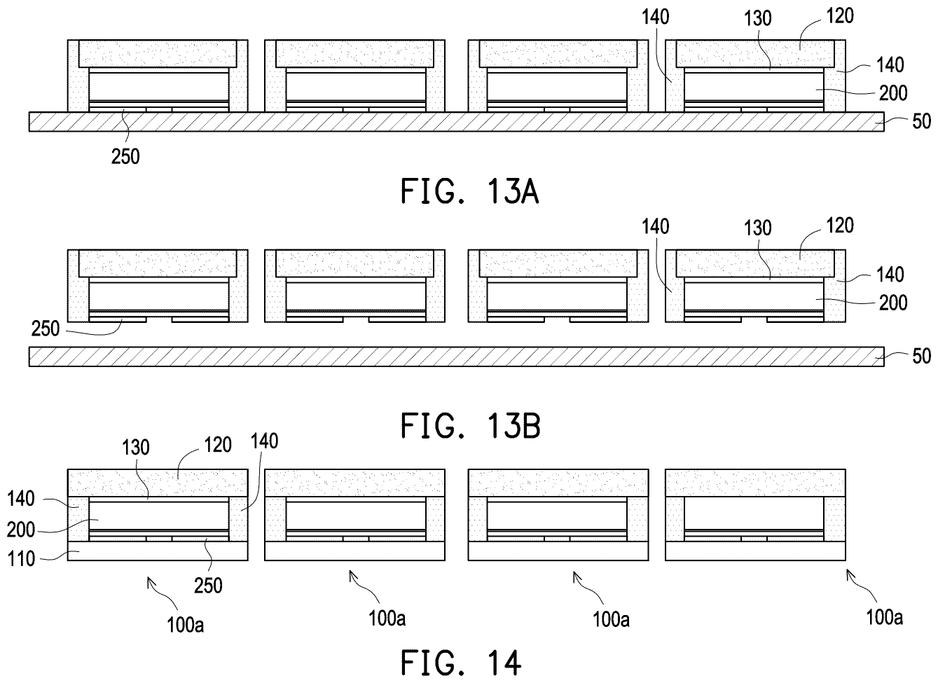

FIGS. 13A and 13B are cross-sectional schematic diagrams illustrating part of the process flow of a manufacturing method of a light-emitting diode structure according to yet another embodiment of the disclosure. Referring to FIGS. 13A and 13B, the manufacturing method of the light-emitting diode structure in this embodiment is similar to the manufacturing method of the light-emitting diode structure in FIGS. 11A to 11I. The main differences between them are as follows. The manufacturing method of the light-emitting diode structure in this embodiment proceeds through the steps in FIGS. 11A to 11E. Then, referring to FIG. 13A, the wavelength conversion layer 120′ and the reflective layer 140′ are cut to form multiple separated wavelength conversion layers 120 and multiple separated reflective layers 140, wherein each wavelength conversion layer 120 covers the top surface of a corresponding reflective layer 140. Next, referring to FIG. 13B, the light-emitting diode chips 200 are separated from the first temporary substrate 50. Then, referring to FIG. 7, each light-emitting diode chip 200, along with the short-pass filter coating 130 and the cut wavelength conversion layer 120, is bonded to a substrate 110. In this way, the fabrication of the light-emitting diode structure 100a is completed.

FIG. 14 is a cross-sectional schematic diagram illustrating one step of the manufacturing method of a light-emitting diode structure according to still another embodiment of the disclosure. Referring to FIG. 14, the manufacturing method of the light-emitting diode structure in this embodiment is similar to the manufacturing method of the light-emitting diode structure in FIGS. 12A to 12F. The main differences between them are as follows. The manufacturing method of the light-emitting diode structure in this embodiment proceeds through the steps in FIGS. 12A to 12C. Then, referring to FIG. 14, the wavelength conversion layer 120′, the reflective layer 140′, and the substrate 110′ are cut to form multiple separated light-emitting diode structures 100a. At the same time, multiple separated wavelength conversion layers 120, multiple separated reflective layers 140, and multiple separated substrates 110 are also formed, wherein each wavelength conversion layer 120 covers the top surface of a corresponding reflective layer 140. In this way, the fabrication of the light-emitting diode structure 100a is completed.

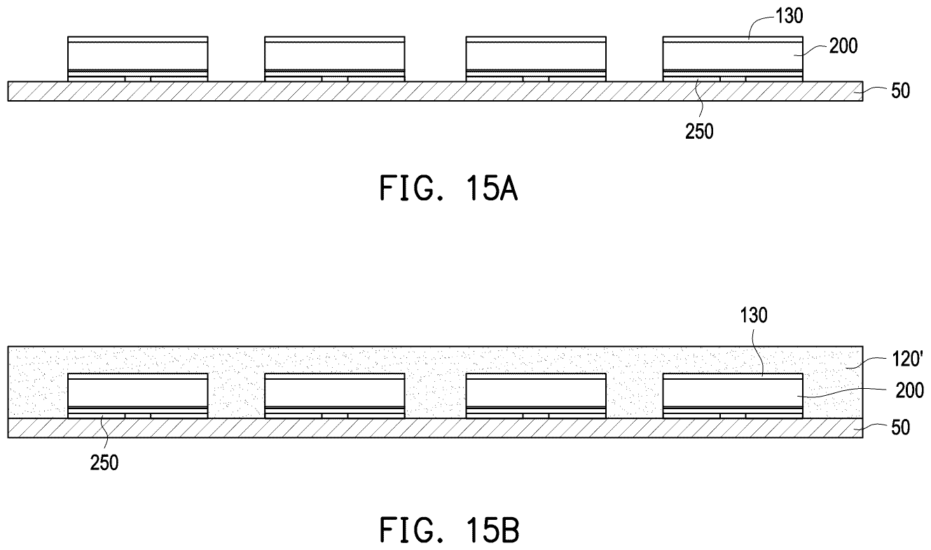

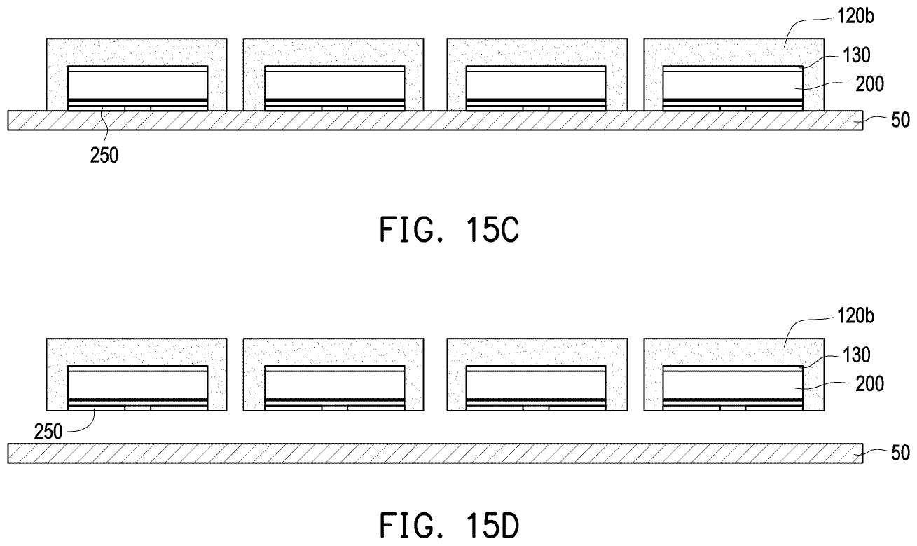

FIGS. 15A to 15D are cross-sectional schematic diagrams illustrating the process flow of a manufacturing method of a light-emitting diode structure according to another embodiment of the disclosure. Referring to FIGS. 15A to 15D, the manufacturing method of the light-emitting diode structure in this embodiment is similar to the manufacturing method of the light-emitting diode structure in FIGS. 11A to 11I. The main differences between them are as follows. The manufacturing method of the light-emitting diode structure in this embodiment includes the following steps. First, referring to FIG. 15A, the light-emitting diode chips 200 are disposed on a first temporary substrate 50, with the electrode 250 facing the first temporary substrate 50. Next, referring to FIG. 15B, the light-emitting diode chips 200 are covered with a wavelength conversion layer 120′, wherein the wavelength conversion layer 120′ covers both the top surface and the side surfaces of the light-emitting diode chips 200. Then, referring to FIG. 15C, the wavelength conversion layer 120′ is cut to form multiple separated wavelength conversion layers 120b, wherein each wavelength conversion layer 120b covers a side of the short-pass filter coating 130 away from the substrate 110 and a side surface of the light-emitting diode chip 200. Next, referring to FIG. 15D, the light-emitting diode chips 200 are separated from the first temporary substrate 50. Then, referring to FIG. 8, each light-emitting diode chip 200, along with the short-pass filter coating 130 and the cut wavelength conversion layer 120b, is bonded to a substrate 110. In this way, the fabrication of the light-emitting diode structure 100b is completed.

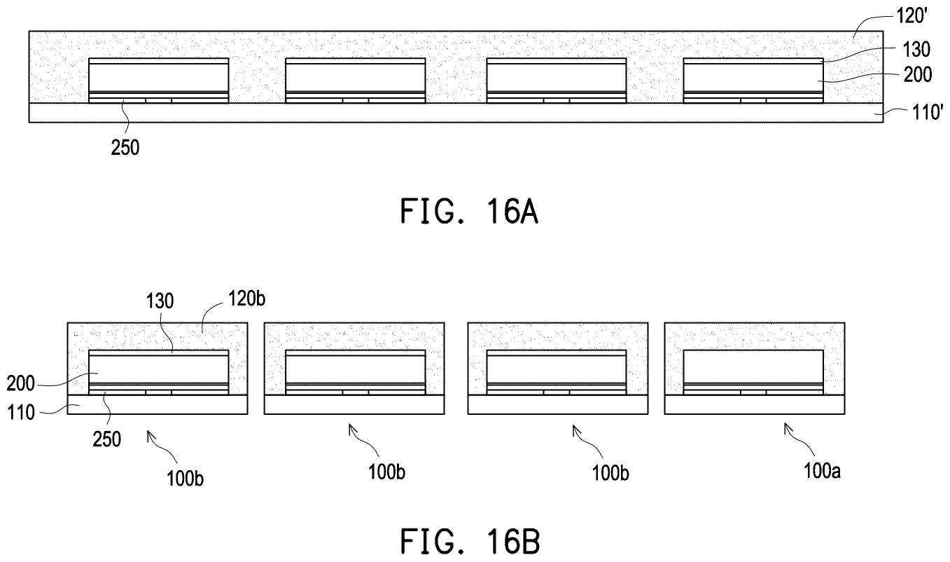

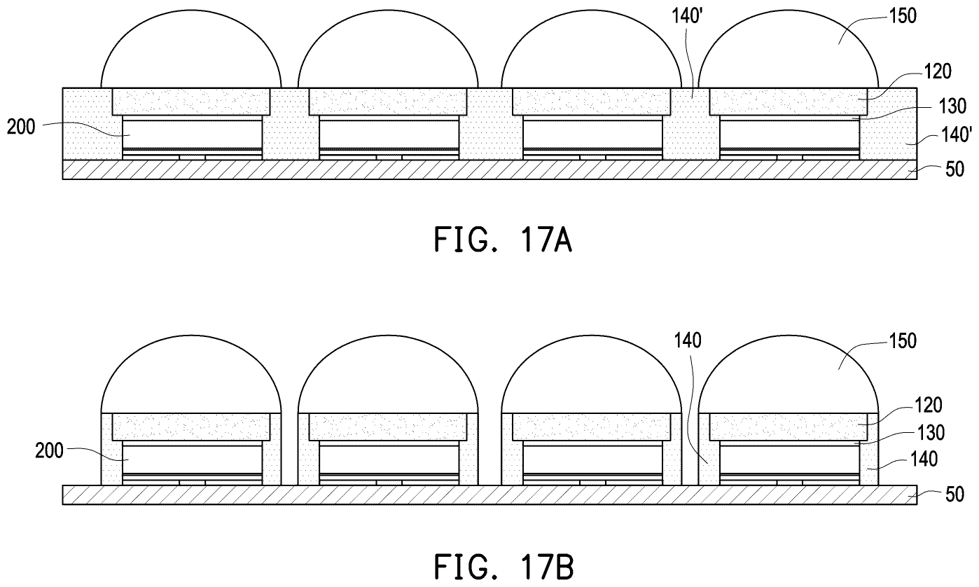

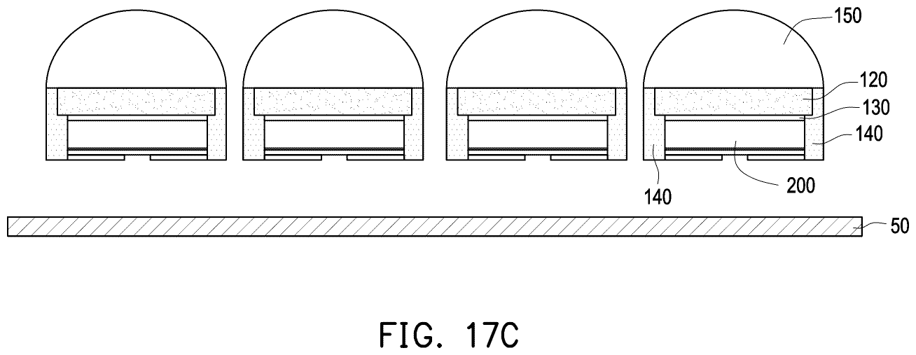

FIGS. 16A and 16B are cross-sectional schematic diagrams illustrating part of the process flow of a manufacturing method of a light-emitting diode structure according to yet another embodiment of the disclosure. Referring to FIGS. 16A and 16B, the manufacturing method of the light-emitting diode structure in this embodiment is similar to the manufacturing method of the light-emitting diode structure in FIGS. 12A to 12F. The main differences between them are as follows. The manufacturing method of the light-emitting diode structure in this embodiment proceeds through the step in FIG. 12A. Then, the step in FIG. 16A is performed, wherein the light-emitting diode chips 200 are covered with a wavelength conversion layer 120′, and the wavelength conversion layer 120′ covers both the top surface and the side surfaces of the light-emitting diode chips 200. Next, referring to FIG. 16B, the wavelength conversion layer 120′ is cut, and the substrate 110′ is also cut to form multiple separated light-emitting diode structures 100b. At the same time, multiple separated wavelength conversion layers 120b and multiple separated substrates 110 are formed, wherein each wavelength conversion layer 120b covers a side of the short-pass filter coating 130 away from the substrate 110 and a side surface of the light-emitting diode chip 200.

FIGS. 17A to 17C are cross-sectional schematic diagrams illustrating part of the process flow of a manufacturing method of a light-emitting diode structure according to still another embodiment of the disclosure. Referring to FIGS. 17A to 17C, the manufacturing method of the light-emitting diode structure in this embodiment is similar to the manufacturing method of the light-emitting diode structure in FIGS. 11A to 11I. The main differences between them are as follows. The manufacturing method of the light-emitting diode structure in this embodiment first proceeds through the steps in FIGS. 11A to 11G. Then, referring to FIG. 17A, multiple lenses 150 are formed on the wavelength conversion layers 120 on the light-emitting diode chips 200. Next, referring to FIG. 17B, the reflective layer 140′ is cut to form multiple separated reflective layers 140, wherein each reflective layer 140 is positioned on a side surface of a corresponding light-emitting diode chip 200.

Then, referring to FIG. 17C, the light-emitting diode chips 200 are separated from the first temporary substrate 50. Next, referring to FIG. 9A, each light-emitting diode chip 200, along with the short-pass filter coating 130 and the cut wavelength conversion layer 120, is bonded to a substrate 110. In this way, the fabrication of the light-emitting diode structure 100c is completed.

In another embodiment, the step of forming multiple lenses 150 on the wavelength conversion layers 120 on the light-emitting diode chips 200 may also be performed after the step in FIG. 12E.

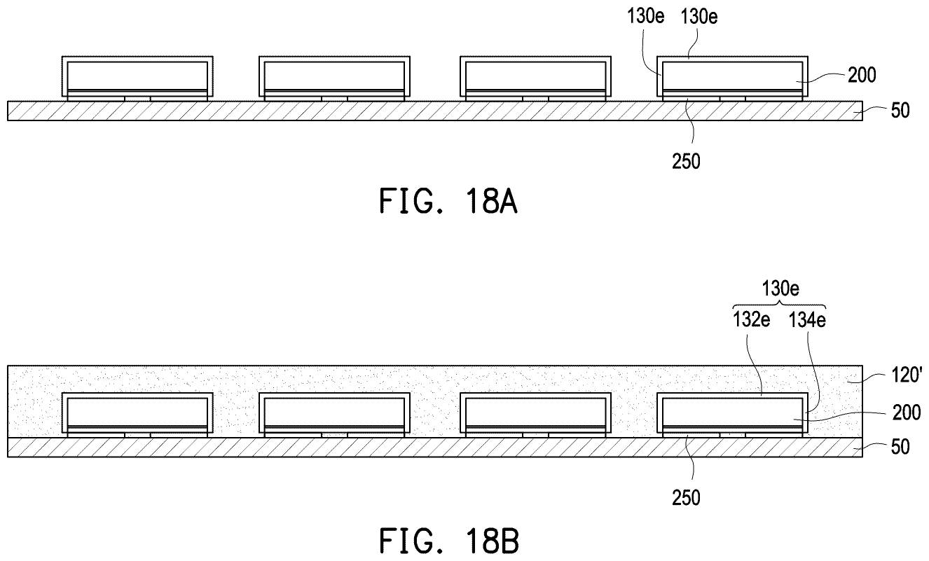

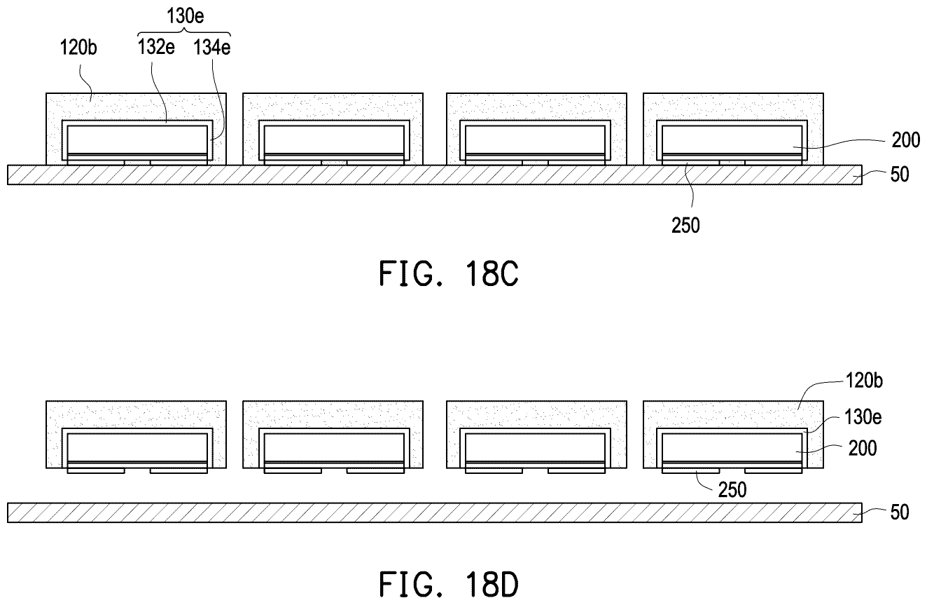

FIGS. 18A to 18D are cross-sectional schematic diagrams illustrating the process flow of a manufacturing method of a light-emitting diode structure according to still another embodiment of the disclosure. The manufacturing method of the light-emitting diode structure in this embodiment is similar to the manufacturing method of the light-emitting diode structure in FIGS. 15A to 15D. The main differences between them are as follows. First, referring to FIG. 18A, a plurality of light-emitting diode chips 200 are provided, wherein each light-emitting diode chip 200 has an electrode 250. A short-pass filter coating 130e is disposed on a side of each light-emitting diode chip 200 facing away from the electrode 250. The short-pass filter coating 130e is also disposed on a side surface of each light-emitting diode chip 200. Then, the light-emitting diode chips 200 are disposed on a first temporary substrate 50, with the electrode 250 facing the first temporary substrate 50. Next, referring to FIG. 18B, the light-emitting diode chips 200 are covered with a wavelength conversion layer 120′, wherein the wavelength conversion layer 120′ covers a portion 132e of the short-pass filter coating 130e disposed on the side of the light-emitting diode chip 200 facing away from the electrode 250 and a portion 134e of the short-pass filter coating 130e disposed on the side surface of the light-emitting diode chip 200. Then, referring to FIG. 18C, the wavelength conversion layer 120′ is cut to form multiple separated wavelength conversion layers 120b, wherein each wavelength conversion layer 120b covers the portion 132e and the portion 134e of the short-pass filter coating 130e. Next, referring to FIG. 18D, the light-emitting diode chips 200 are separated from the first temporary substrate 50. Then, referring to FIG. 10A, each light-emitting diode chip 200, along with the short-pass filter coating 130e and the cut wavelength conversion layer 120b, is bonded to a substrate 110. In this way, the fabrication of the light-emitting diode structure 100e is completed.

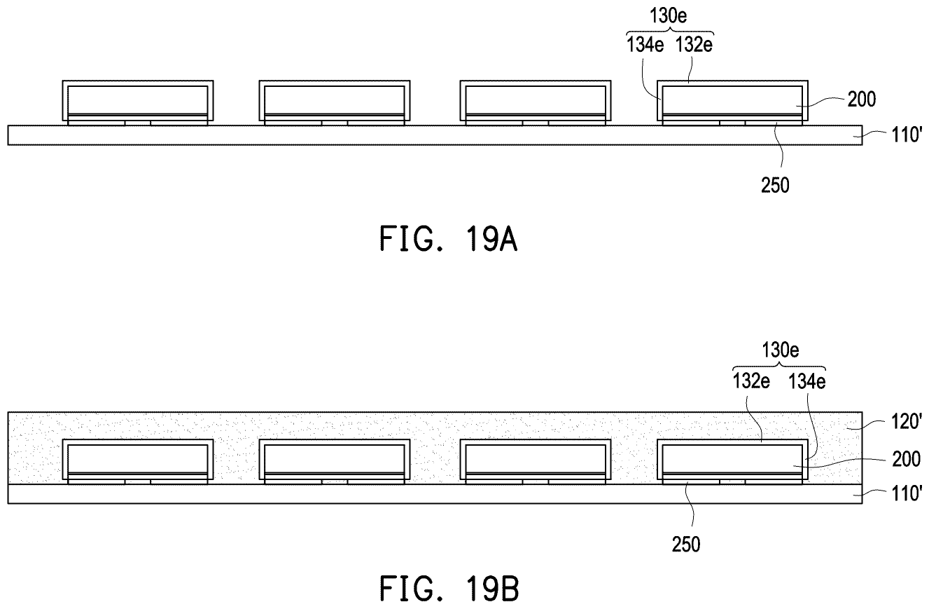

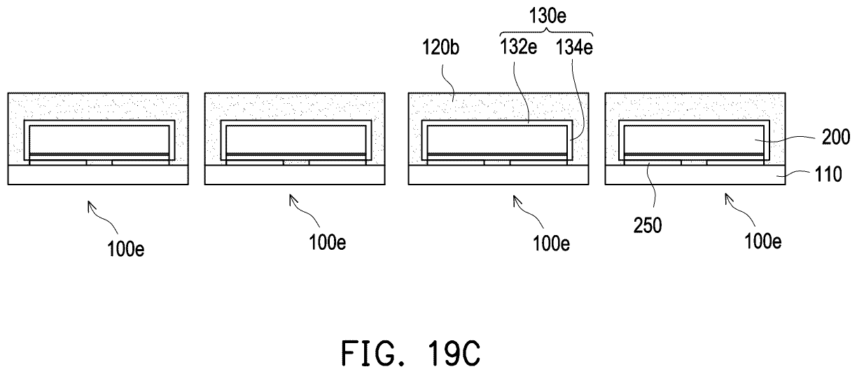

FIGS. 19A to 19C are cross-sectional schematic diagrams illustrating the process flow of a manufacturing method of a light-emitting diode structure according to another embodiment of the disclosure. The manufacturing method of the light-emitting diode structure in this embodiment is similar to the manufacturing method of the light-emitting diode structure in FIGS. 16A and 16B. The main differences between them are as follows. First, referring to FIG. 19A, a plurality of light-emitting diode chips 200 are provided, wherein each light-emitting diode chip 200 has an electrode 250. A short-pass filter coating 130e is disposed on a side of each light-emitting diode chip 200 facing away from the electrode 250. The short-pass filter coating 130e is also disposed on a side surface of each light-emitting diode chip 200. Then, the light-emitting diode chips 200 are disposed on a substrate 110′, with the electrode 250 facing the substrate 110′. Next, referring to FIG. 19B, the light-emitting diode chips 200 are covered with a wavelength conversion layer 120′, wherein the wavelength conversion layer 120′ covers a portion 132e of the short-pass filter coating 130e disposed on the side of the light-emitting diode chip 200 facing away from the electrode 250 and a portion 134e of the short-pass filter coating 130e disposed on the side surface of the light-emitting diode chip 200. Then, referring to FIG. 19C, the wavelength conversion layer 120′ is cut, and the substrate 110′ is also cut to form multiple separated light-emitting diode structures 100e. At the same time, multiple separated wavelength conversion layers 120b and multiple separated substrates 110 are formed, wherein each wavelength conversion layer 120b covers the portion 132e and the portion 134e of the short-pass filter coating 130e. In this way, the fabrication of the light-emitting diode structure 100e is completed.

In the light-emitting diode structure and the manufacturing method in the embodiments of the disclosure, the short-pass filter coating allows the first light beam emitted by the light-emitting diode chip to pass through and reflects the second light beam from the wavelength conversion layer. As a result, loss of the second light beam transmitted into the interior of the light-emitting diode chip is effectively reduced, thereby improving the light efficiency of the light-emitting diode structure.

Finally, it should be noted that the above embodiments are only used to illustrate the technical solutions of the disclosure and are not intended to limit the disclosure. Although the disclosure has been described in detail with reference to the foregoing embodiments, those skilled in the art should understand that modifications may still be made to the technical solutions described in the foregoing embodiments, or some or all of the technical features may be replaced with equivalents. These modifications or replacements do not cause the essence of the corresponding technical solutions to deviate from the scope of the technical solutions in the embodiments of the disclosure.

What is claimed is:

1. A light-emitting diode structure, comprising:
a substrate;
a light-emitting diode chip, disposed on the substrate in a flip-chip manner and used to emit a first light beam;
a wavelength conversion layer, disposed on the light-emitting diode chip and used to convert a part of the first light beam into a second light beam, wherein a wavelength of the first light beam is less than a wavelength of the second light beam; and
a short-pass filter coating, disposed between the wavelength conversion layer and the light-emitting diode chip, allowing the first light beam to pass through and reflecting the second light beam.

2. The light-emitting diode structure according to claim 1, wherein the wavelength conversion layer is a phosphor layer or a quantum dot layer.

3. The light-emitting diode structure according to claim 1, wherein the short-pass filter coating is disposed on a side of the light-emitting diode chip away from the substrate.

4. The light-emitting diode structure according to claim 3, wherein the wavelength conversion layer is disposed on a side of the short-pass filter coating away from the substrate, and the light-emitting diode structure further comprises a reflective layer disposed on a side surface of the light-emitting diode chip.

5. The light-emitting diode structure according to claim 4, wherein the reflective layer covers a side surface of the wavelength conversion layer.

6. The light-emitting diode structure according to claim 4, wherein the wavelength conversion layer covers a top surface of the reflective layer.

7. The light-emitting diode structure according to claim 3, wherein the wavelength conversion layer covers a side of the short-pass filter coating away from the substrate and a side surface of the light-emitting diode chip.

8. The light-emitting diode structure according to claim 1, wherein the short-pass filter coating covers a side of the light-emitting diode chip away from the substrate and a side surface of the light-emitting diode chip, and the wavelength conversion layer covers a side of the short-pass filter coating away from the substrate and a side of the short-pass filter coating away from the side surface of the light-emitting diode chip.

9. The light-emitting diode structure according to claim 1, wherein the light-emitting diode chip comprises:
a growth substrate, wherein the short-pass filter coating is disposed on a surface of the growth substrate facing away from the substrate;
a first type semiconductor layer, disposed between the growth substrate and the substrate;
a light-emitting layer, disposed between the first type semiconductor layer and the substrate;
a second type semiconductor layer, disposed between the light-emitting layer and the substrate; and
an electrode, disposed between the second type semiconductor layer and the substrate and electrically connected to the substrate.

10. The light-emitting diode structure according to claim 1, further comprising a lens disposed on the wavelength conversion layer.

11. A manufacturing method of a light-emitting diode structure, comprising:
providing a plurality of light-emitting diode chips, wherein each of the plurality of light-emitting diode chips has an electrode, and a short-pass filter coating is disposed on a side of the each of the plurality of light-emitting diode chips facing away from the electrode;
disposing the plurality of light-emitting diode chips on a first temporary substrate, with the electrode facing the first temporary substrate;
covering the plurality of light-emitting diode chips with a wavelength conversion layer;
cutting the wavelength conversion layer; and
separating the plurality of light-emitting diode chips from the first temporary substrate, and bonding the each of the plurality of light-emitting diode chips along with the short-pass filter coating and the cut wavelength conversion layer to a substrate.

12. The manufacturing method of the light-emitting diode structure according to claim 11, further comprising:
before disposing the plurality of light-emitting diode chips on the first temporary substrate, first disposing the plurality of light-emitting diode chips on a second temporary substrate, with the electrode facing a direction away from the second temporary substrate;
filling a reflective layer in a gap between the plurality of adjacent light-emitting diode chips on the second temporary substrate;
separating the plurality of light-emitting diode chips, along with the reflective layer and the short-pass filter coating, from the second temporary substrate; and
after cutting the wavelength conversion layer, cutting the reflective layer.

13. The manufacturing method of the light-emitting diode structure according to claim 11, further comprising:
after cutting the wavelength conversion layer, respectively forming a plurality of lenses on the wavelength conversion layer on the plurality of light-emitting diode chips.

14. The manufacturing method of the light-emitting diode structure according to claim 11, wherein covering the plurality of light-emitting diode chips with the wavelength conversion layer comprises covering a top surface and a side surface of the plurality of light-emitting diode chips with the wavelength conversion layer.

15. The manufacturing method of the light-emitting diode structure according to claim 11, wherein the short-pass filter coating is also disposed on a side surface of the each of the plurality of light-emitting diode chips, and covering the plurality of light-emitting diode chips with the wavelength conversion layer comprises covering a portion of the short-pass filter coating located on the side of the each of the plurality of light-emitting diode chips facing away from the electrode with the wavelength conversion layer, and covering a portion of the short-pass filter coating located on the side surface of the each of the plurality of light-emitting diode chips with the wavelength conversion layer.

16. A manufacturing method of a light-emitting diode structure, comprising:
providing a plurality of light-emitting diode chips, wherein each of the plurality of light-emitting diode chips comprises an electrode, and a short-pass filter coating is disposed on a side of the each of the plurality of light-emitting diode chips facing away from the electrode;
disposing the plurality of light-emitting diode chips on a substrate, with the electrode facing the substrate;
covering the plurality of light-emitting diode chips with a wavelength conversion layer;
cutting the wavelength conversion layer; and
cutting the substrate to form a plurality of separated light-emitting diode structures.

17. The manufacturing method of the light-emitting diode structure according to claim 16, further comprising:
filling a reflective layer in a gap between the plurality of adjacent light-emitting diode chips on the substrate; and
cutting the reflective layer when cutting the substrate.

18. The manufacturing method of the light-emitting diode structure according to claim 16, further comprising:
after cutting the wavelength conversion layer, respectively forming a plurality of lenses on the wavelength conversion layer on the plurality of light-emitting diode chips.

19. The manufacturing method of the light-emitting diode structure according to claim 16, wherein covering the plurality of light-emitting diode chips with the wavelength conversion layer comprises covering a top surface and a side surface of the plurality of light-emitting diode chips with the wavelength conversion layer.

20. The manufacturing method of the light-emitting diode structure according to claim 16, wherein the short-pass filter coating is also disposed on a side surface of the each of the plurality of light-emitting diode chips, and covering the plurality of light-emitting diode chips with the wavelength conversion layer comprises covering a portion of the short-pass filter coating located on the side of the each of the plurality of light-emitting diode chips facing away from the electrode with the wavelength conversion layer, and covering a portion of the short-pass filter coating located on the side surface of the each of the plurality of light-emitting diode chips with the wavelength conversion layer.
